(19) United States
(12) Patent Application Publication
(10) Pub. No.: US 2008/0061654 A1
(43) Pub. Date: Mar. 13, 2008

(54) Ultrasonic actuator and manufacturing method of vibration member thereof

(75) Inventor: Takashi Matsuo, Itami-shi (JP)

Correspondence Address: SIDLEY AUSTIN LLP, 717 NORTH HARWOOD, SUITE 3400, DALLAS, TX, 75201, US

(73) Assignee: KONICA MINOLTA OPTO, INC.

(21) Appl. No.: 11/897,298

(22) Filed: Aug. 30, 2007

(30) Foreign Application Priority Data
Sep. 8, 2006 (JP) 2006-244052

(51) Int. Cl. H01L 41/187; H01L 41/18; H01L 41/22

(52) U.S. Cl. 310/323.01; 29/25.35; 310/358

(57) ABSTRACT

An ultrasonic actuator including: a vibration member, which comprises a plurality of piezoelectric displacement sections each being expanded and contracted by electric signals, and a connection section to connect the plurality of piezoelectric displacement sections, wherein the vibration member is vibrated by resonance of the plurality of piezoelectric displacement sections; and a movement member which generates relative movement to the vibration member by being pressed and contacted with the vibration member, wherein the plurality of piezoelectric displacement sections and the connection section are formed in one body with one and the same material.

### CROSS REFERENCE TO RELATED APPLICATION

The present application is based on Japanese Patent Application No. 2006-244052 filed with Japanese Patent Office on Sep. 8, 2006, the entire content of which is hereby incorporated by reference.

### BACKGROUND OF THE INVENTION

1. Field of the Invention

This invention relates an ultrasonic actuator and a manufacturing method of a vibration member thereof, more particularly, relates to an ultrasonic actuator for generating relative movement by pressing and contacting a vibration member to a movement member.

2. Prior Art

In recent years, many attempts of utilizing an ultrasonic actuator in various movement apparatuses have been tried. In general, an ultrasonic actuator is an actuator for generating relative motion by friction force between a movement member and a vibration member contacting thereto with pressure by inputting drive signal into a vibration member having a piezoelectric element, which is an electric-mechanical energy transducer element, to allow the vibration member to conduct expand-contract motion to cause an elliptical vibration (including a circle vibration) with a part of the vibration member.

With respect to the vibration member, for example, unexamined Japanese Patent Application Publication No. 2001-54291 discloses a truss type ultrasonic actuator, in which two piezoelectric elements are disposed so as to cross each other, and for example, Japanese Registered Patent No. 3523488 discloses a parallel type ultrasonic actuator, in which two piezoelectric elements are disposed so as to be parallel with each other.

Here, the outline of the vibration member in a conventional ultrasonic actuator will be described.

Firstly, the structure of the vibration members will be described by using FIGS. 14 and 18. FIG. 14 illustrates the structure of a conventional truss type vibration member 10 and FIG. 18 illustrates the structure of a conventional parallel type vibration member 10.

The truss type vibration member 10 and the parallel vibration member 10 respectively include two piezoelectric elements 152 and 153, a base member 105, a chip member 106. The chip member 106 is connected with one end of respective piezoelectric elements 152 and 153 by using adhesive agent. On the other hand, a base member 105 is adhered onto the other end of the piezoelectric elements 152 and 153 by the adhesive agent.

Next, inherent modes of the vibration member having structure described above will be described by using FIGS. 15(a)-(b) and 19(a)-(b). FIGS. 15(a) and 15(b) respectively illustrate aspects of the deformation of the conventional truss type vibration member 10 in a common phase mode and a reverse phase mode. FIGS. 19(a) and 19(b) respectively illustrate aspects of the deformation of the conventional parallel type vibration member 10 in a common phase mode and a reverse phase mode.

The common phase mode is a mode where the two piezoelectric elements 152 and 153 expand and contract with the same phase mode. As illustrated in FIGS. 15(a) and 19(a), two piezoelectric elements 152 and 153 expand and contract in the same direction and the chip member 106 respectively vibrate in arrow directions P and R. The reverse phase mode is a mode where the two piezoelectric elements 152 and 153 expand and contract with the reverse phase mode. As illustrated in FIGS. 15(b) and 19(b), two piezoelectric elements 152 and 153 expand and contract in the opposite directions to each other and the chip member 106 respectively vibrates in arrow directions Q, S1 and S2.

By using these common phase mode and reverse phase mode, it is possible to move the chip member 106 so as to draw elliptical trajectory (including circular trajectory), namely to conduct elliptical vibration (including circle vibration) by respectively setting the resonance frequencies of the piezoelectric elements 152 and 153 with a predetermined relationship.

With respect to the drive method of causing elliptical vibration with a chip member by using the common phase mode and the reverse phase mode, two driving methods, a phase difference drive and a single phase drive are known.

In the phase difference drive, firstly, the resonance frequencies in the common phase mode and the reverse phase mode is substantially coincided. Secondary, the alternate voltages having frequencies close to the resonance frequencies with different phases are respectively applied to two piezoelectric elements. Then, elliptical vibration, where the shape and the rotation direction thereof are determined in response to the voltage and the phase difference of the alternative voltages, is generated. In the single phase drive, elliptical vibration is generated by applying a single phase alternative voltage to a piezoelectric element at the frequency between two resonance frequencies by shifting the resonance frequencies of the common phase mode and the reverse phase mode by a predetermined value. The shape of the elliptical vibration is determined by the resonance frequency difference and the frequency. Switching the piezoelectric element, onto which the alternative voltage is applied, can reverse the rotation direction of the elliptical vibration.

By the way, in the vibration member having this type of structure, the sensitivity of right and left symmetry such as position error and characteristic error of these two piezoelectric elements, against the elliptical trajectory is very high.

In the common phase mode and the reverse phase mode, in case when the right and left symmetry of two piezoelectric elements collapses, since resonance Q decreases and vibration amplitude is attenuated, the elliptical trajectory becomes small. Thus, reductions of output of the ultrasonic actuator (the reduction of the speed of the movement member and thrust) and direction difference occur. With respect to the causes of the collapse of the right and left symmetry, there are two causes, which are the right-and-left position error of two piezoelectric elements and resonance frequency differences among piezoelectric elements themselves. The error sensitivity of any one of these causes against the elliptical trajectory is high as described above.

FIG. 13 illustrates elliptical trajectory of the truss type vibration member in case when there are the right-and-left position error of two piezoelectric elements, and the characteristic difference between the piezoelectric elements. As illustrated in FIG. 13, in case when there is the right-and-left position error of two piezoelectric elements, and the characteristic difference between the piezoelectric elements, it is recognized that the elliptical trajectory becomes small comparing with a designed value.

Further, even though the positions of two piezoelectric elements are symmetric in right and left positions, in case when the two piezoelectric elements are shifted inside or outside against the designed value, since the resonance frequencies in the common phase mode and the reverse phase mode shift from the designed value and the elliptical trajectory varies, reductions of output of the ultrasonic actuator (the reduction of the speed and thrust force of the movement member) and direction difference and dispersion by each vibration member occur.

Hereinafter, the aspects of the changes of resonance frequency and elliptical focus in case when the positions of two piezoelectric elements shift inside or outside against the designed value will be described by using FIGS. 16, 17, 20 and 21. FIG. 16 illustrates a graph illustrating the relationship between the position error of the piezoelectric element and the resonance frequency in the truss type vibration member. FIG. 17 illustrates an aspect of the elliptical trajectory change due to the position error of the piezoelectric element in the truss type vibration member. FIG. 20 illustrates a graph showing the relationship between the position error of the piezoelectric element and the resonance frequency in the parallel type vibration member. FIG. 21 illustrates an aspect of the elliptical trajectory change due to the position error of the piezoelectric element in the parallel type vibration member.

As illustrated in FIGS. 16, 17, 20 and 21, in any one of the truss type vibration member and the parallel vibration member, it is recognized that the resonance frequency and the elliptical trajectory largely change based on the position error of the two piezoelectric elements. The all data illustrated in FIGS. 13, 16, 17, 20 and 21 is based on simulation results. In FIGS. 16, 17, 20 and 21, with respect to an element position error, in case when two piezoelectric elements shift “d” inside, it is set as “−d” and in case when two piezoelectric elements shift “d” outside, it is set as “+d”. An X-axis and a Y-axis in FIGS. 17 and 21 respectively correspond to the X-axis and the Y-axis in FIGS. 14 and 18. Further, FIGS. 13, 17 and 21 illustrate elliptical trajectory in a single phase drive. However, also in the phase difference drive, the elliptical trajectory largely changes due to the shift of resonance frequency as the same as described above.

As described above, in the vibration member having two piezoelectric elements, it is important to regulate the position errors and characteristic error of two piezoelectric elements to secure the right and left symmetry with high accuracy.

However, in the vibration member disclosed in Unexamined Japanese Patent Application Publication No. 2001-54291 and Japanese Registered Patent No. 3523488, as described above, since two independent piezoelectric elements are placed between a base member and a chip member, and connected therewith by adhesive agent to manufacture the vibration member, it seems difficult to easily secure the right and left symmetry with high accuracy. Namely, since in order to manufacture the vibration member, it is necessary to provide two piezoelectric elements, determine the relative position of the two piezoelectric elements against the base member and the chip member with high accuracy, fix and connect them with the base member and the chip member by the adhesive agent, following problems are anticipated. Firstly, since the maximum dispersion of the resonance frequency of the piezoelectric element itself between lots is normally up to 20%, there is a case that it is necessary to measure the characteristic of all the single units of the piezoelectric elements and to have process for paring the elements having similar characteristics by conducting a selection process before entering assembly. Thus it is anticipated that the processes become complicated. Secondary, when conducting assembly of the vibration member, the assembly jig for accurately determining the position and inclination of two piezoelectric elements is used. In case when the jig structure is simple, the position of the piezoelectric element tends to shift and a high accuracy jig is required to accurately determine the position. Further, since the mechanism for holding the piezoelectric elements not to be shifted while hardening adhesive agent or while conveying the vibration member, becomes necessary, there is a concern of inviting tendency that the assembly jig becomes complicated; the cost increases due to the large-sized tendency of the assembly jig; and productivity drops down. Thirdly, there are four points where an adhesive layer exists in the structure for connecting two piezoelectric elements, a base member and a chip member into a shape of triangle or rectangular shape. There are problems that these adhesive layers attenuate the vibration, elliptical trajectory becomes small and output of the actuator deceases. Fourthly, the position error of the piezoelectric element and the right-and-left symmetry of the characteristic largely affect the elliptical trajectory particularly in case when a material having high Q-value (a high Q-value material) is used for the piezoelectric element material. Since the attenuation of the vibration amplitude of the high Q-value material is small when the material is in a resonant state (for example, PTZ, which belongs to a hard category), there are advantages that large movement amount can be obtained and at the same time, the heat generation is low when it is in a resonant state, and the drive efficiency is high. However, on the other hand, the characteristic largely changes against the frequency (frequency characteristic is sharp) and the elliptical trajectory largely changes against the small change of the resonance frequency in the common phase drive mode and the reverse phase drive mode. Further, the difference between the resonance frequencies of two piezoelectric elements largely affects the elliptical trajectory, and the dispersion of the output of the ultrasonic actuator becomes very large. Thus, there are problems that in order to avoid these inferences, the high Q-value material cannot be used, which blocks the tendency toward the high output and high drive efficiency of the ultrasonic actuator.

It is therefore an object of the present invention is to provide an ultrasonic actuator, to solve the problems described above, which is capable of obtaining high output and high drive efficiency, and the manufacturing method of the vibration member thereof by securing the right-and-left symmetry of a plurality of piezoelectric elements without having the complexity of a device and cost increase in the ultrasonic actuator including a vibration member, which is vibrated by the resonance of a plurality of piezoelectric displacement sections expanded and contracted by electrical signal, and a movement member for generating relative movement against the vibration member.

### SUMMARY

An embodiment reflecting one aspect of the present invention to solve the above-mentioned problems is an ultrasonic actuator including: a vibration member, which comprises a plurality of piezoelectric displacement sections each being expanded and contracted by electric signals, and a connection section to connect the plurality of piezoelectric displacement sections, wherein the vibration member is vibrated by resonance of the plurality of piezoelectric displacement sections; and a movement member which generates relative movement to the vibration member by being pressed and contacted with the vibration member, wherein the plurality of piezoelectric displacement sections and the connection section are formed in one body with one and the same base material.

An embodiment reflecting another aspect of the present invention is a manufacturing method of a vibration member of an ultrasonic actuator, the vibration member including a plurality of piezoelectric displacement sections and a connection section to connect the piezoelectric displacement sections, the manufacturing method of the vibration member including the steps of: forming a piezoelectric base material for making the piezoelectric displacement sections, by alternately layering a piezoelectric layer and an electrode layer; forming a connection layer for making the connection section on the piezoelectric base material, the connection layer being thicker than the piezoelectric layer and being formed with same material as the piezoelectric layer; cutting the piezoelectric base material to form a groove, from an opposite side of the connection layer, so that the connection layer remains; cutting the piezoelectric base material to form each separate vibration member.

An embodiment reflecting another aspect of the present invention is a manufacturing method a vibration member including the steps of: forming a piezoelectric base material for making the piezoelectric displacement sections and the connection section, by alternately layering a piezoelectric layer and an electrode layer; cutting the piezoelectric base material, to form a groove on the piezoelectric base material, in a vertical direction to a layered surface of the piezoelectric base material so that the connection layer remains; cutting the piezoelectric base material to separate each vibration member.

An embodiment reflecting another aspect of the present invention is a manufacturing method a vibration member including the steps of: forming a piezoelectric base material for making the piezoelectric displacement sections and the connection section, by alternately layering a piezoelectric layer and an electrode layer; cutting the piezoelectric base material, to form a groove on the piezoelectric base material, in a vertical direction to a layered surface of the piezoelectric base material; cutting the piezoelectric base material so that the connection section remains and each vibration member is separated.

An embodiment reflecting still another aspect of the present invention is a manufacturing method a vibration member of an ultrasonic actuator including the steps of: forming the connection section by forming a pattern on a base member; forming the piezoelectric displacement sections by alternately printing or transferring a piezoelectric layer and an electrode layer on the connection section so that each of the plurality of piezoelectric displacement sections are separately formed; separating the piezoelectric base material from the connection section to form each vibration member.

### BRIEF DESCRIPTION OF THE DRAWINGS

These and other objects, advantages and features of the invention will become apparent from the following description thereof taken in conjunction with the accompanying drawings in which:

FIG. 1 illustrates a total structure of an ultrasonic actuator of an embodiment 1 of the present invention;

FIG. 2 illustrates an external perspective view of a parallel type vibration member of an embodiment 1 of the invention;

FIG. 3 illustrates an external perspective view of a parallel type vibration member of the other example of an embodiment 1 of the invention;

FIGS. 4(a)-4(d) illustrate a manufacturing process of the parallel type vibration member of an embodiment 1 of the ultrasonic actuator of the invention;

FIG. 5 illustrates an external perspective view of a parallel type vibration member of an embodiment 2 of the invention;

FIGS. 6(a)-6(b) illustrate an inside electrode configuration of a parallel type vibration member of an embodiment 2 of the invention;

FIGS. 7(a)-7(b) illustrate a manufacturing process of the parallel type vibration member of an embodiment 2 of the ultrasonic actuator of the invention;

FIG. 8 illustrates an external perspective view of a truss type vibration member of an embodiment 3 of the invention;

FIGS. 9(a)-9(b) illustrate an inside electrode configuration of a truss type vibration member of an embodiment 3 of the invention;

FIGS. 10(a)-10(b) illustrate a manufacturing process of the truss type vibration member of an embodiment 3 of the ultrasonic actuator of the invention;

FIG. 11 illustrates an external perspective view of a parallel type vibration member of the other example of an embodiment 2 of the invention;

FIGS. 12(a)-12(c) illustrate a manufacturing process of the parallel type vibration member of the other example of an embodiment 1 of the ultrasonic actuator of the invention;

FIG. 13 illustrates the aspect of the elliptical trajectory change due to right and left error of the piezoelectric element position and the characteristic differences between piezoelectric elements of a conventional truss type vibration member;

FIG. 14 illustrates structure of the conventional truss type vibration member;

FIGS. 15(a)-15(b) illustrate an aspect of deformation in an inherent mode of the conventional truss type vibration member;

FIG. 16 illustrates a graph showing the relationship between the position error of the piezoelectric element in the conventional truss type vibration member and resonance frequency;

FIG. 17 illustrates the aspect of elliptical trajectory change based on the position error of the piezoelectric element in a conventional truss type vibration member;

FIG. 18 illustrates the structure of a conventional parallel type vibration member;

FIG. 19(a)-19(b) illustrate the aspect of deformation change of the conventional parallel type vibration member in an inherent mode;

FIG. 20 illustrates a graph showing the relationship between the position error of the piezoelectric element and the resonance frequency of the conventional parallel type vibration member; and

FIG. 21 illustrates a graph showing the aspect of the elliptical trajectory change due to the position error of the piezoelectric element of the conventional parallel type vibration member.

### DETAILED DESCRIPTION OF THE PREFERRED EMBODIMENTS

An embodiment of an ultrasonic actuator of the invention will be described based on the drawings hereinafter. The present invention will be explained based on an embodiment illustrated in the drawings. However, the present invention is not limited to these embodiments.

### Embodiment 1

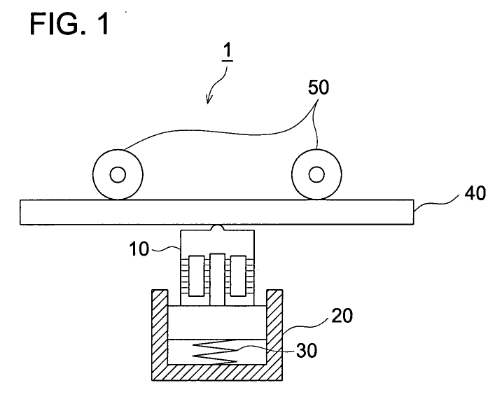

Firstly, the structure of an ultrasonic actuator of an embodiment 1 will be described by using FIG. 1. FIG. 1 illustrates the outline of a total structure of an ultrasonic actuator 1.

As illustrated in FIG. 1, an ultrasonic actuator 1 includes a parallel type vibration member 10, a guide member 20, a pressure member 30, a movement member 40 and rollers 50. The ultrasonic actuator 1 is an actuator for generating relative motion by friction force between the movement member 40 and the vibration member 10 contacting thereto with pressure by inputting a drive signal into the vibration member 10 having a piezoelectric member 101, which is an electric-mechanical energy transducer element and will be described later, to allow the vibration member 10 to generate expand-contract motions to move a part of vibration member 10 so as to cause elliptical trajectory (including circular trajectory), namely to cause an elliptical vibration (including a circle vibration) with a part of the vibration member.

The parallel type vibration member 10 is supported by the guide member 20 so as to be capable of moving upward and downward along with the guide member 20. The parallel vibration member 10 is contacted with the movement member 40 with pressure by a pressure member 30, such as a coil spring. The movement member 40 is supported by the rollers 50 so as to be capable of moving right and left directions along a linear guide, which is not shown. In case when elliptical vibration is excited on the parallel type vibration member 10, the friction force moves the movement member 40. In case when the rotation direction of the elliptical vibration is clockwise, the movement member moves right, and in case the rotation direction of the elliptical vibration is counterclockwise, the movement member moves left.

A metal material, such as a plate or a bar of stainless steel forms the movement member 40. In order to prevent abrasive wear due to the friction with the vibration member 10, a surface hardening process, such as, a nitriding process is applied onto the movement member 40. In the ultrasonic actuator of an embodiment 1 of the invention, an example of a linear drive is shown. However, it may also be possible to use a rotation member for the movement member 40 to conduct rotation drive.

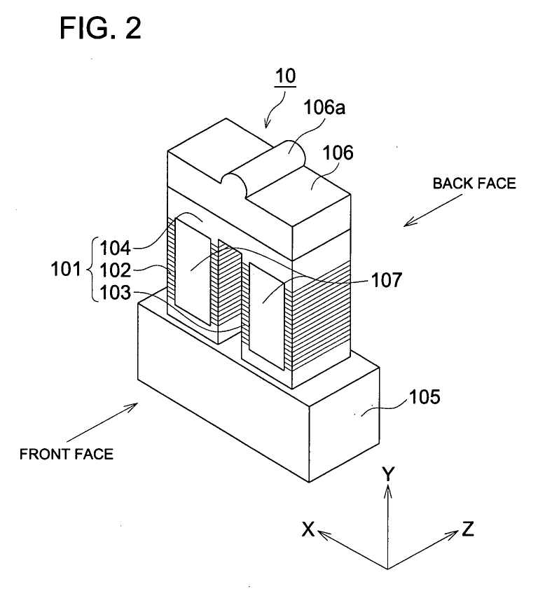

Next, the structure of the parallel type vibration member 10 will be described by using FIG. 2. FIG. 2 illustrates an external perspective view of a parallel type vibration member 10 of an embodiment 1 of the invention.

As shown in FIG. 2, the parallel type vibration member 10 includes a piezoelectric member 101, a base member 105 and a chip member 106. Adhesive agent connects the chip member 106, which corresponds to the contact member of the invention, to the piezoelectric member 101. On the other hand, adhesive agent contacts the other end of the piezoelectric member 101 with the base member 105. With respect to the adhesive agent, epoxy adhesive agent, which has high adhesive strength and high rigidity, is used.

Piezoelectric displacement sections 102 and 103 and a connection section 104 structure the piezoelectric member 101. Two piezoelectric displacement sections 102 and 103 are disposed in parallel via the connection section 104 and formed in one body into U-shape.

A piezoelectric base material 100 showing piezoelectric characteristic, such as PTZ, which will be described later, forms the piezoelectric member 101. The parallel portions of the U-shape correspond to the piezoelectric displacement sections 102 and 103, which conduct movement, and the portion connecting two piezoelectric displacement sections 102 and 103 corresponds to the connection section 104. The piezoelectric displacement sections 102 and 103 correspond to a layered type piezoelectric element of the present invention, where a piezoelectric ceramic thin plate having thickness of 10 μm (hereinafter, it will be said “a piezoelectric thin plate”) and an inside electrode layer formed by silver or silver palladium is alternately layered in a Y-direction. Outside electrodes 107 are formed on respective piezoelectric displacement sections 102 and 103 so that the inside electrodes are connected in every other layer. In FIG. 2, the outside electrodes 107 are formed on the respective rear surfaces of the piezoelectric displacement sections 102 and 103 so that the inside electrodes, which are not connected to the outside electrodes 107 on the front surface, are connected thereto.

Lead lines and FPC (Flexible Printed Circuit-board), which are not shown, are connected to the outside electrodes 107, which also connect the outside electrodes 107 with a drive circuit. Inputting voltage between the outside electrodes 107 expands (contracts) the respective piezoelectric thin films in the Y-direction and the piezoelectric displacement members 102 and 103 displace in the Y-direction accordingly.

The same PZT material as the piezoelectric displacement sections 102 and 103 structures the connection section 104. However, since no electrode is formed on the connection section 104, the connection section 104 itself does not displace.

The resonance of the piezoelectric member 101 excites the chip member 106 and an edge section 106a causes elliptical vibration. The edge section 106a contacts with the movement member 40 with pressure, and repeat friction force having the same period as the vibration period of the edge section 106a occurs. This repeat-friction force becomes the drive force for moving the movement member 40.

With respect to the material of the chip member 106, in order to prevent wear, ceramics having high solidity, such as alumina and zirconia, or hard metal is used. Further, with respect to the base member 105, a metal material, such as, stainless steel having low attenuation and characteristics to be easily manufactured, is utilized.

In order to conduct the single layer drive in the structure of the piezoelectric member 101 as described above, the length, cross-sectional shape and distance of the piezoelectric displacement sections 102 and 103 are adjusted so that the difference of the resonance frequencies of the common phase mode and the reverse mode becomes a predetermined value.

In the common phase mode, the piezoelectric displacement sections 102 and 103 expand and contract in the same phase and the front edge section 106a vibrates in the Y-direction. In the reverse mode, the piezoelectric displacement sections 102 and 103 expand and contract in the reverse phase and connection section 104 and chip member 106 conducts rotational motion on the XY-plane. As a result, the front edge section 106a vibrates in the X-direction. Further, by inputting an alternate voltage having frequency between respective resonance frequencies onto any one of piezoelectric displacement sections 102 and 103, two modes respectively having slightly shifted phase are excited. As a result, elliptical vibration, into which vibration in the Y-direction and vibration in the X-direction have been synthesized, is generated with the front edge section 106a. Switching from the piezoelectric displacement section 102 to the piezoelectric displacement section 103 or vise versa, to which the alternative voltage is applied, can change the rotation direction of the ellipse.

As described above, in an ultrasonic actuator 1 related to the invention, since the piezoelectric member 101 is formed in one body from the same piezoelectric base member 100, which will be described later, by cutting, the positions of the two piezoelectric displacement sections 102 and 103 are determined by processing accuracy. Thus, the piezoelectric member 101 can be manufactured with extremely high accuracy. Further, it becomes hard that the difference of characteristic, such as resonance frequencies between the piezoelectric displacement sections 102 and 103, occurs. Thus, right and left symmetry of the two piezoelectric displacement sections 102 and 103 can be secured with high accuracy.

Accordingly, the discrete dispersion of the vibration member 10 can be decreased and high output, which is close to the designed value, can be obtained. Further, since it is possible to use the piezoelectric material having high Q-value, large elliptical vibration can be obtained and the output and drive efficiency of the ultrasonic actuator 1 can be improved.

Further, comparing with conventional ultrasonic actuator, the assembly jig of the vibration member 10 can be simplified. Furthermore, the selection and the paring process of the piezoelectric elements prior to the assembly become unnecessary.

Further, since two piezoelectric displacement sections 102 and 103 are formed in one body, comparing with conventional piezoelectric displacement section, the number of adhesive layers in the connection structure can be decreased by two positions. Thus, the attenuation of vibration can be regulated and output can be improved.

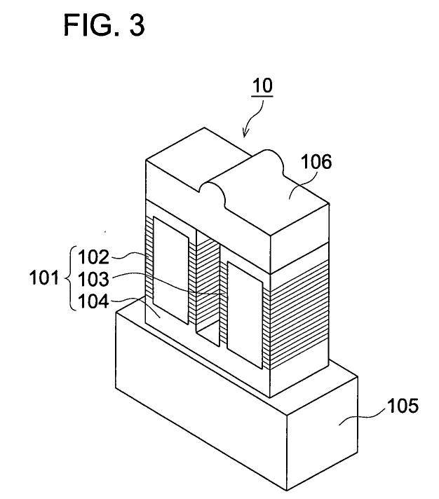

In the ultrasonic actuator 1 of an embodiment of the invention, as illustrated in FIG. 2, the connection section 104 of the piezoelectric member 101 is disposed to contact with the chip member 106. However, as illustrated in FIG. 3, the piezoelectric member 101 may be turned upside down and disposed so that the connection section 104 is connected with the base member 105.

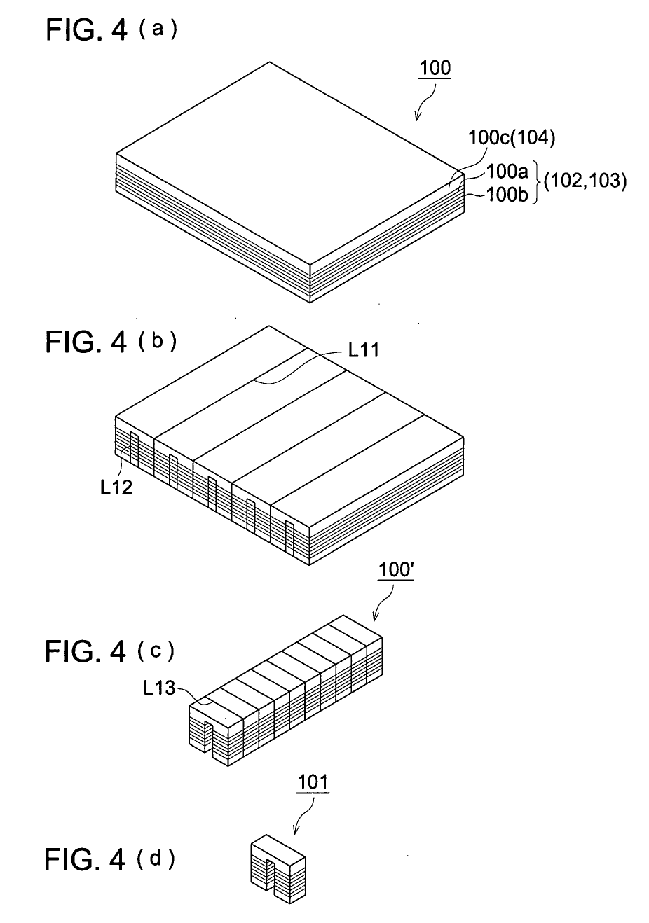

Next, a manufacturing method of such structure of the piezoelectric member 101 will be described by using FIGS. 4(a)-4(b). FIGS. 4(a)-4(d) illustrate a manufacturing process of the piezoelectric member 101.

The piezoelectric base member 100 is a sintered piezoelectric block, in which a rectangular piezoelectric thin plate 100a and an inside electrode layer 100b are alternately layered as illustrated in FIG. 4(a).

Since a top stacked layer 100c becomes the connection section 104, the stacked layer 100c is formed by a layer having thickness of 1 mm-several mm, which is thicker than the layer of the piezoelectric displacement sections 102 and 103.

Next, the piezoelectric base member 100 is cut by a dicing machine along lines L11 and L12 as illustrated in FIG. 4(b) to cut out of a U-shaped longitudinal piezoelectric base member 100′ as illustrated in FIG. 4(c).

Next, the piezoelectric base member 100′ is cut by the dicing machine along a line L13 with a thickness of the piezoelectric member 101 as illustrated in FIG. 4(c) to obtain the piezoelectric member 101 as illustrated in FIG. 4(d). After that, a print process of the outside electrodes and a polarization process, which are not shown, are conducted.

Since the positional relationship between the piezoelectric displacement sections 102 and 103 is determined only by the process accuracy of the machine, an extremely accurate shape can be obtained. Since two piezoelectric displacement sections 102 and 103 are cut out from the same piezoelectric base member 100 as a pair, the characteristic becomes substantially the same.

Still, the sheet type chip member 106 may have been adhered onto the piezoelectric base member 100 illustrated in FIG. 4(a), and it may be cut out when the piezoelectric member 101 is cut out. Based on this arrangement, adhesive work when assembling the vibration member 10 can be reduced.

### Embodiment 2

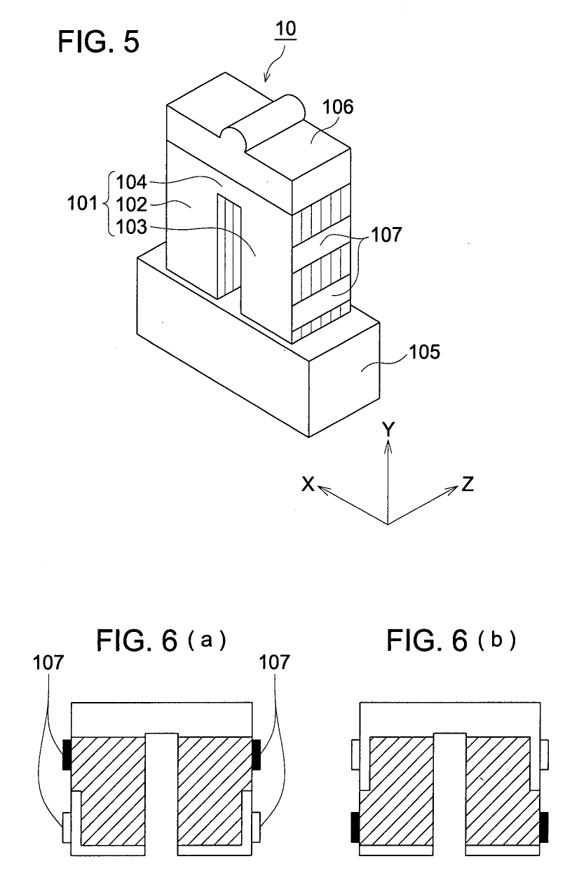

Next, the ultrasonic actuator 1 of an embodiment 2 will be described. Since the main portion of the structure is substantially the same as the ultrasonic actuator 1 of an embodiment 1, detailed description will be omitted and piezoelectric displacement sections 102 and 103 of the piezoelectric member 101, which are different structure from a first embodiment, will be described by referring to FIG. 5. FIG. 5 illustrates an external perspective view of a parallel type vibration member 10 of an embodiment 2 of the invention.

The piezoelectric thin plate 100a and the inside electrode layer 100b are alternately layered in Y-direction in the piezoelectric displacement sections 102 and 103 of a first embodiment 1. However, as illustrated in FIG. 5, the piezoelectric thin plate 100a and the inside electrode layer 100b are alternately layered in the Z-direction in the piezoelectric displacement sections 102 and 103 of an embodiment 2.

Thus, the pickup direction of the movement becomes Y-direction (31 direction). Comparing with the piezoelectric displacement sections 102 and 103 of an embodiment 1, even though the movement amount per a unit voltage decreases, following advantages are expected.

Namely, since the piezoelectric displacement sections 102 and 103 have weakness of tension in a layered direction, comparing with the piezoelectric displacement sections 102 and 103 of an embodiment 1, the strength in the displacement direction increases and a large displacement amount can be obtained. Further, the manufacturing method, which will be described later, will be simplified.

Next, the inside electrode structure of the piezoelectric displacement sections 102 and 103 will be described by referring to FIG. 6(a)-6(b). FIGS. 6(a)-6(b) illustrate an inside electrode configuration of a parallel type vibration member of an embodiment 2 of the invention.

The electrode structures illustrated in FIGS. 6(a)-6(b) are alternately layered in the Z-direction in the piezoelectric displacement sections 102 and 103. Since, with regard to the outside electrodes 107, two electrodes are formed on the same surface, the inside electrode structure is arranged so that one of the outside electrodes 107 is isolated from the other electrode in each layer.

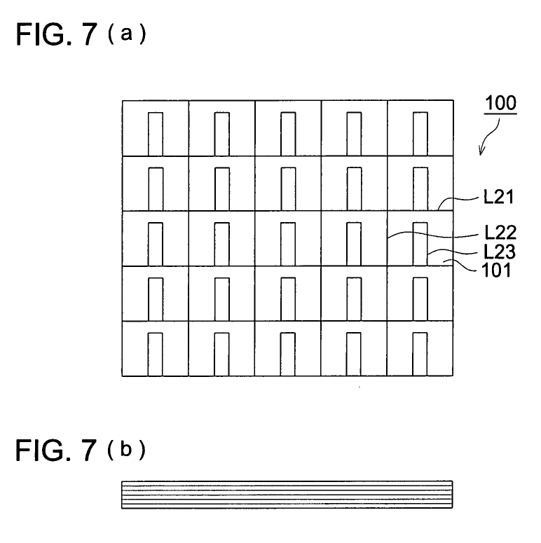

Next, the manufacturing method of such a structure of the piezoelectric member 101 will be described by referring to FIGS. 7(a)-7(b). FIG. 7(a) illustrates a plan view of the piezoelectric base member 100 and FIG. 7(b) illustrates a side view of the piezoelectric base member 100.

The piezoelectric base member 100 is a sintered piezoelectric block, in which rectangular piezoelectric thin plate 100a and an inside electrode layer 100b are alternately layered, in the same way as the piezoelectric base member 100 in an embodiment 1.

Next, for example, a dicing machine cuts such piezoelectric base member 100 into the shape of the piezoelectric member 101 along the lines L21, L22 and L23 as illustrated in FIG. 7(a) to obtain the piezoelectric member 101. After that, a print process of the outside electrodes and a polarization process are conducted. Since, the number of cutting processes is small, comparing with the manufacturing method, manufacturing processes can be simplified and the manufacturing cost can be reduced.

### Embodiment 3

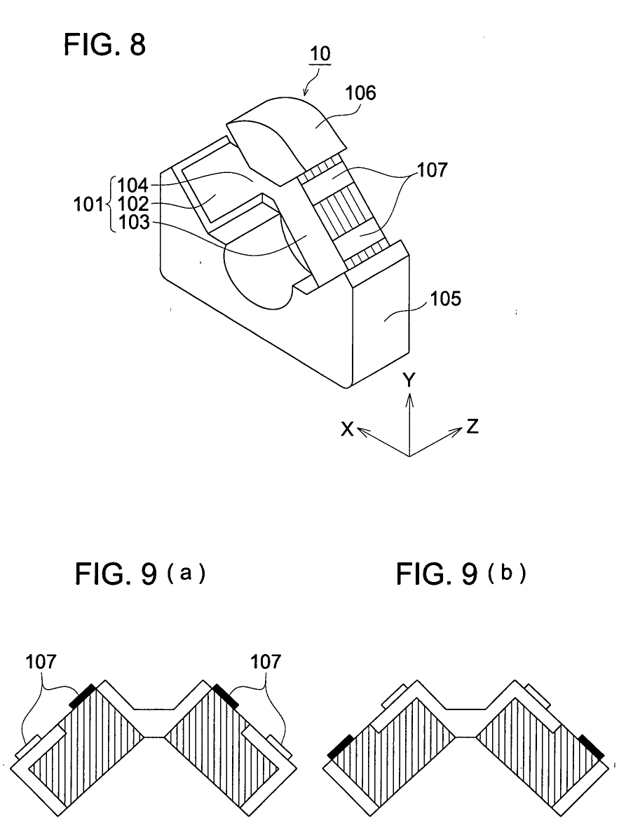

Next, the actuator 1 of an embodiment 3 will be described. Since the main portion of the structure is substantially the same as the ultrasonic actuator of embodiments 1 and 2, detailed description will be omitted and the piezoelectric displacement sections 102 and 103 of the piezoelectric member 101, which are different structure of first and second embodiments, will be described by referring to FIG. 8. FIG. 8 illustrates an external perspective view of a parallel type vibration member 10 of an embodiment 3 of the invention.

The truss type vibration member 10 includes the piezoelectric member 101, the base member 105 and the chip member 106, the same as the parallel vibration member 10 in embodiments 1 and 2 as illustrated in FIG. 8. An adhesive agent adheres the chip member 106 to one end of the piezoelectric member 101. On the other hand, the base member 105 is adhered onto the other end of the piezoelectric member 101 by the adhesive agent. Still, with respect to the adhesive agent, epoxy adhesive agent having a high adhesive strength rigidity is used.

The piezoelectric displacement sections 102 and 103, and connection section 104 structure the piezoelectric member 101. Two piezoelectric displacement sections 102 and 103 are disposed via the connection section 104 such that each one end-surface of the piezoelectric displacement sections 102 and 103 forms an angle of 90° each other in one body into a reverse V-shape.

With respect to the piezoelectric displacement sections 102 and 103, the same as the piezoelectric displacement sections 102 and 103 in an embodiment 2, the piezoelectric thin plate 100a and the inside electrode layer 100b are alternately layered in the Z-direction. Since the inside electrode structure is the same as the electrode structure in an embodiment 2 as illustrated in FIGS. 9(a)-(b), the description will be omitted here.

Lead lines and FPC (Flexible Printed Circuit-board), which are not shown, are connected with the outside electrodes 107, which also connect the outside electrodes 107 to a drive circuit. Inputting voltage between the outside electrodes 107 expands (contracts) the respective piezoelectric thin films in the Z-direction and the piezoelectric displacement members 102 and 103 shift in the longitudinal direction.

Further, the length, the cross sectional shape and the position against the chip member 106 of the piezoelectric displacement sections 102 and 103 are adjusted so that the differences between the resonance frequencies in the common phase mode and the reverse phase mode becomes a predetermined difference.

In the common phase mode, the piezoelectric displacement sections 102 and 103 expand and contract in the same phase and the chip member 106 vibrates in the Y-direction. In the reverse mode, the piezoelectric displacement sections 102 and 103 expand and contract in the reverse phase and chip member 106 vibrates in the X-direction. Further, by inputting an alternate voltage having frequency between respective resonance frequencies onto any one of piezoelectric displacement sections 102 and 103, two modes respectively having slightly shifted phases are excited.

As a result, elliptical vibration, into which vibration in the Y-direction and vibration in the X-direction have been synthesized, is generated with the chip member 106. Switching the piezoelectric displacement section, to which alternate voltage is applied, from the piezoelectric displacement section 102 to the piezoelectric displacement section 103 or vise versa, can change the rotation direction of the ellipse.

As described above, in the ultrasonic actuator 1 of an embodiment 3, in the same as the ultrasonic actuator 1 of embodiments 1 and 2, since the piezoelectric member 101 is formed in one body from the same piezoelectric base member 100 by cutting, the positions of the two piezoelectric displacement sections 102 and 103 are determined by processing accuracy. Thus, the piezoelectric member 101 can be manufactured with extremely high accuracy. Further, it becomes hard that the difference of characteristic, such as resonance frequencies between the piezoelectric displacement sections 102 and 103, occurs. Thus, right and left symmetry of the two piezoelectric displacement sections 102 and 103 can be secured with high accuracy.

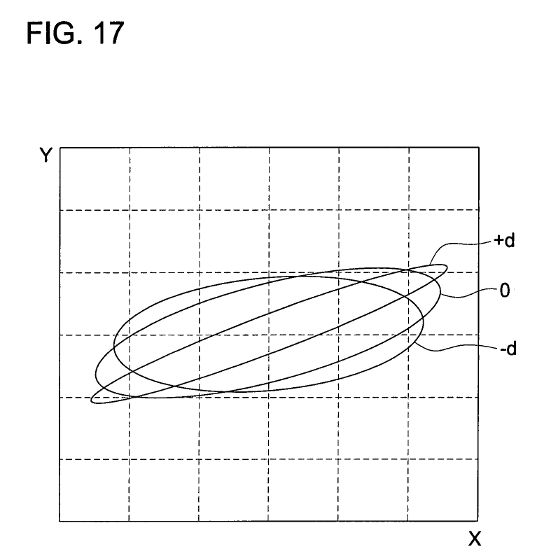

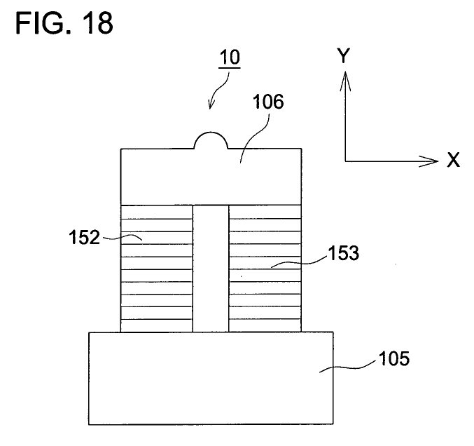

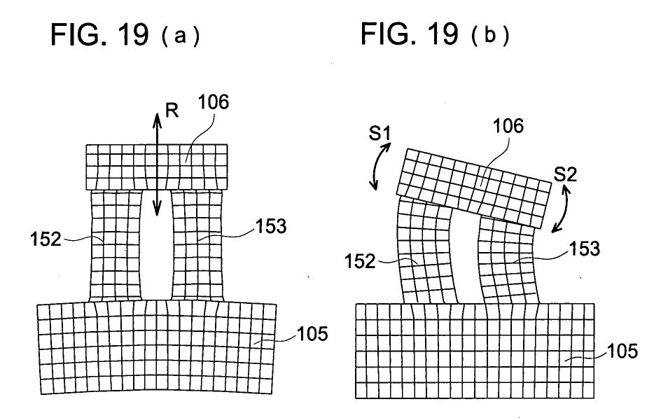

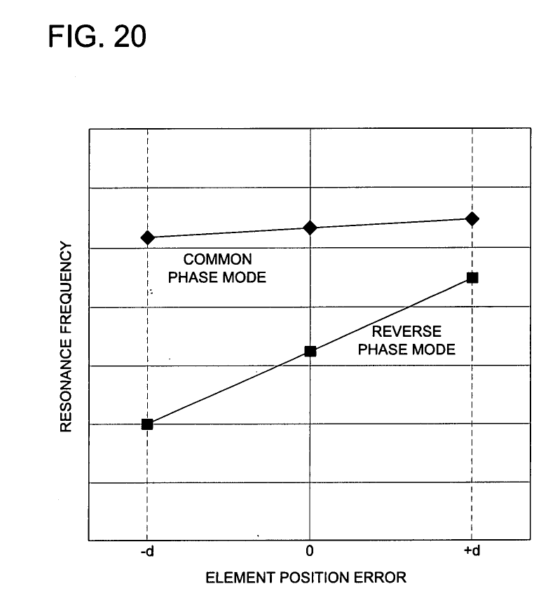

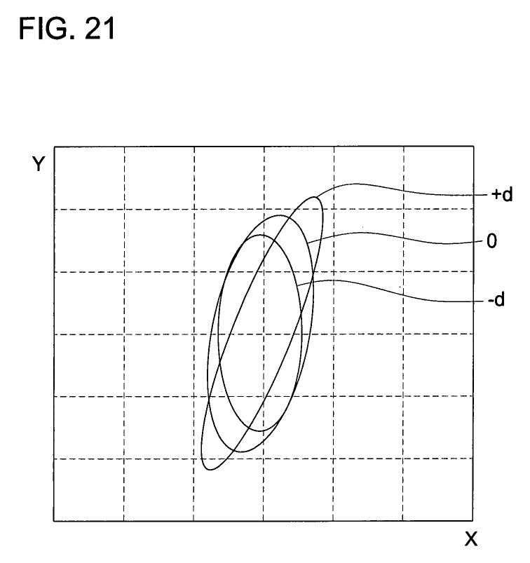

As understood from the elliptical trajectory described above and illustrated in FIGS. 17 and 21, in the truss type vibration member, the amplitude in a lateral direction (X-direction) is large and in the parallel type vibration member, the vibration in the vertical direction (Y-direction) is large. In the relationship between the elliptical trajectory shape and the drive performance, since lateral direction vibration amplitude affects the velocity of the movement member and vertical direction vibration amplitude affects the thrust force of the movement member, the truss type vibration member generates high velocity type output and the parallel type vibration member generates high thrust force type output.

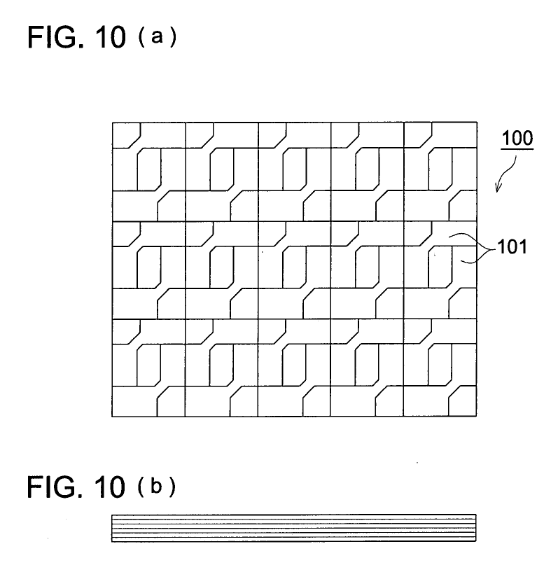

Next, a manufacturing method of such structure of the piezoelectric member 101 will be described by using FIGS. 10(a)-10(b). The piezoelectric member is similar to manufacturing method of the piezoelectric member 101 of an embodiment 2 as illustrated in FIG. 10(a). The piezoelectric base member 100 is cut by, for example, a dicing machine into the shape of the piezoelectric member 101 to obtain the piezoelectric member 101. After that, a print process of the outside electrodes and a polarization process are conducted.

The invention has been described by referring to embodiments. The present invention is not limited to the above embodiments and various change and modification may be made without departing from the scope of the invention.

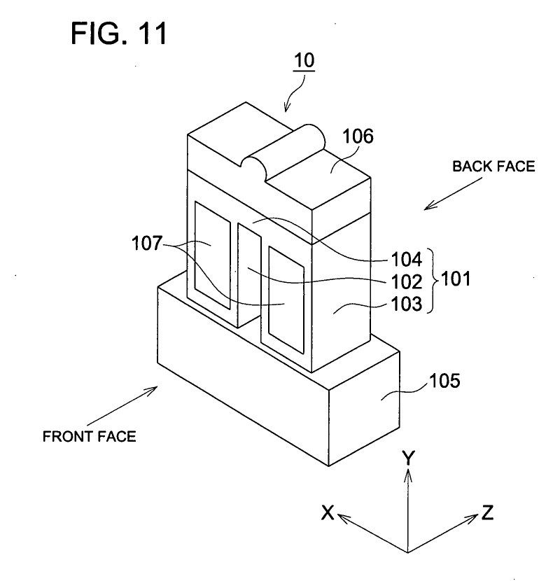

For example, the piezoelectric members 101 in embodiments 2 and 3 have layered structure where the piezoelectric thin plate 100a and the inside electrode layer 100b are alternately layered as described above. However, as illustrated in FIG. 11, the piezoelectric member 101 may be a single piezoelectric ceramics. FIG. 11 illustrates an external perspective view of a parallel type vibration member of the other example of an embodiment 2 of the invention

The piezoelectric member 101 is a single piezoelectric ceramics having outside electrodes 107 in both surfaces of the front surface and the rear surface and polarized in the thickness direction (Z-direction). The manufacturing method includes a step of sintering the piezoelectric member 101 after forming into the shape illustrated in FIG. 11. Alternatively, in the same as the case of layering the piezoelectric member, the piezoelectric member 101 may be cut out from a sintered piezoelectric base member 100 (piezoelectric block). In case when the piezoelectric member 101 is formed into a single piezoelectric ceramics structure, the drive voltage becomes high. However, the manufacturing process is simple and manufacturing cost can be reduced.

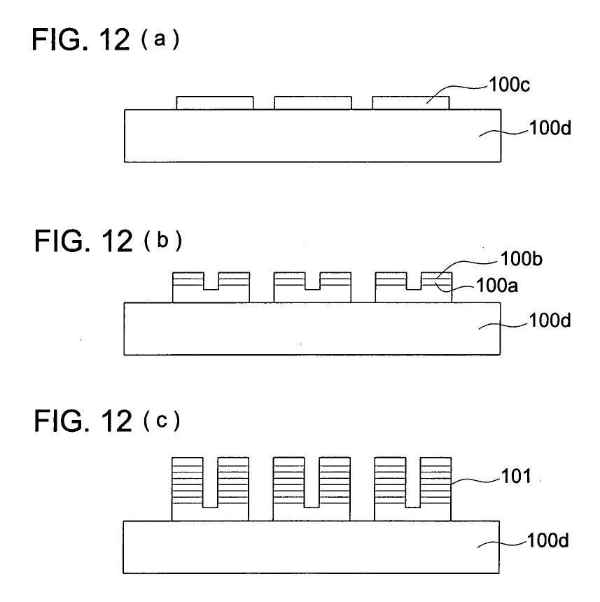

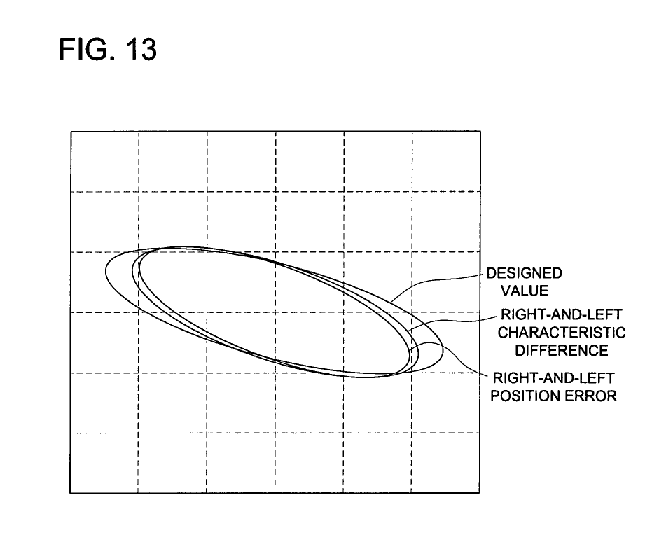

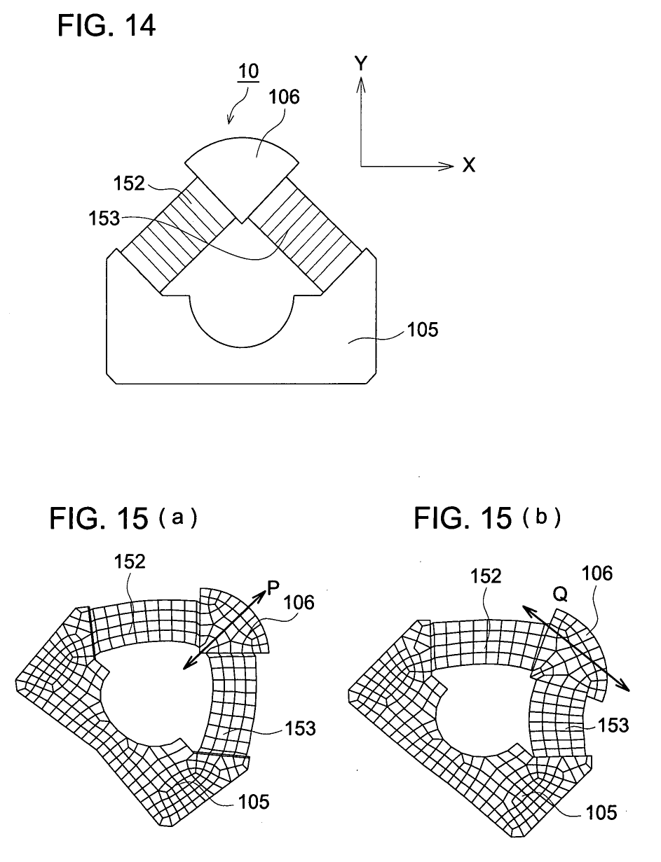

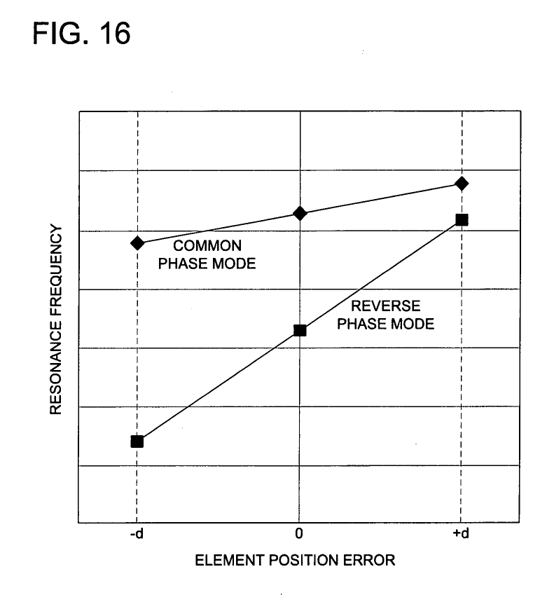

Further, the piezoelectric member 101 may be formed in one body not by cutting. FIGS. 12(a)-12(c) illustrate a manufacturing process of the piezoelectric member 101 in an embodiment 1, for example, by a screen-printing. In FIG. 12(a), connection section 100c is formed by pattern formation on base material 100d, and as illustrated from FIG. 12(b) to FIG. 12(C), alternately printed are the piezoelectric thin plate 100a and the inside electrode layer 100b in a cross-sectional shape, sintering them after completing printing all layers, and lastly take out from the base member 100d to obtain the piezoelectric member 101. Comparing with embodiments 1-3, there is an advantage that the shape can be freely designed. Thus, in the case of the piezoelectric member 101 in an embodiment 2, the structure where the both ends of the piezoelectric displacement sections 102 and 103 is connected can be possible and the strength thereof can be improved.

According to this invention, a plurality of piezoelectric displacement sections and a connection section is formed in one body from the same piezoelectric base member. Namely, position errors and right and left symmetry of characteristic differences of the plurality of piezoelectric sections can be secured with high accuracy by uniformly forming the plurality of piezoelectric displacement sections. Thus, dispersion of the performances of an ultrasonic actuator can be regulated. Further, since a high-Q piezoelectric material can be used for the plurality of piezoelectric displacement sections, high output and high drive efficiency can be steadily obtained.

What is claimed is:

1. An ultrasonic actuator comprising:
a vibration member, which comprises a plurality of piezoelectric displacement sections each being expanded and contracted by electric signals, and a connection section to connect the plurality of piezoelectric displacement sections, wherein the vibration member is vibrated by resonance of the plurality of piezoelectric displacement sections; and
a movement member which generates relative movement to the vibration member by being pressed and contacted with the vibration member,
wherein the plurality of piezoelectric displacement sections and the connection section are formed in one body with one and the same material.

2. The ultrasonic actuator of claim 1,
wherein the plurality of piezoelectric displacement sections are structured with one of a layered type piezoelectric element and a single piezoelectric ceramic.

3. The ultrasonic actuator of claim 1,
wherein the plurality of piezoelectric displacement sections and the connection section are formed in one body by cutting the piezoelectric base material.

4. The ultrasonic actuator of claim 1, wherein the plurality of piezoelectric displacement sections and the connection section are formed in one body by screen printing or by transfer method.

5. The ultrasonic actuator of claim 1, wherein the plurality of piezoelectric displacement sections is disposed so that each one end surface of the plurality of piezoelectric movement sections forms a predetermined angle with each other.

6. The ultrasonic actuator of claim 1, wherein each of the plurality of piezoelectric displacement sections is disposed so as to be parallel with each other.

7. A manufacturing method a vibration member of an ultrasonic actuator, the vibration member including a plurality of piezoelectric displacement sections and a connection section to connect the piezoelectric displacement sections, the manufacturing method of the vibration member comprising:
forming a piezoelectric base material for making the piezoelectric displacement sections, by alternately layering a piezoelectric layer and an electrode layer;
forming a connection layer for making the connection section on the piezoelectric base material, the connection layer being thicker than the piezoelectric layer and being formed with same material as the piezoelectric layer;
cutting the piezoelectric base material to form a groove, from an opposite side of the connection layer, so that the connection layer remains;
cutting the piezoelectric base material to form each separate vibration member.

8. A manufacturing method a vibration member of an ultrasonic actuator, the vibration member including a plurality of piezoelectric displacement sections and a connection section to connect the piezoelectric displacement sections, the manufacturing method of the vibration member comprising:
forming a piezoelectric base material for making the piezoelectric displacement sections and the connection section, by alternately layering a piezoelectric layer and an electrode layer;
cutting the piezoelectric base material, to form a groove on the piezoelectric base material, in a vertical direction to a layered surface of the piezoelectric base material so that the connection layer remains;
cutting the piezoelectric base material to separate each vibration member.

9. A manufacturing method a vibration member of an ultrasonic actuator, the vibration member including a plurality of piezoelectric displacement sections and a connection section to connect the piezoelectric displacement sections, the manufacturing method of the vibration member comprising:
forming a piezoelectric base material for making the piezoelectric displacement sections and the connection section, by alternately layering a piezoelectric layer and an electrode layer;
cutting the piezoelectric base material, to form a groove on the piezoelectric base material, in a vertical direction to a layered surface of the piezoelectric base material;
cutting the piezoelectric base material so that the connection section remains and each vibration member is separated.

10. A manufacturing method a vibration member of an ultrasonic actuator, the vibration member including a plurality of piezoelectric displacement sections and a connection section to connect the piezoelectric displacement sections, the manufacturing method of the vibration member comprising:
forming the connection section by forming a pattern on a base member;
forming the piezoelectric displacement sections by alternately printing or transferring a piezoelectric layer and an electrode layer on the connection section so that each of the plurality of piezoelectric displacement sections are separately formed;
separating the piezoelectric base material from the connection section to form each vibration member.
